(19) United States
(12) Patent Application Publication
(10) Pub. No.: US 2012/0100713 A1
(43) Pub. Date: Apr. 26, 2012

(54) METHOD FOR MANUFACTURING SEMICONDUCTOR DEVICE

(75) Inventor: Sung Soo KIM, Yongin (KR)

(73) Assignee: Hynix Semiconductor Inc., Icheon (KR)

(21) Appl. No.: 13/237,244

(22) Filed: Sep. 20, 2011

(30) Foreign Application Priority Data
Oct. 22, 2010 (KR) 10-2010-0103519

(51) Int. Cl. H01L 21/28

(52) U.S. Cl. 438/656; 438/652; 257/E21.158

(57) ABSTRACT

A semiconductor device and a method for forming the same are disclosed. In the method for manufacturing the semiconductor device, a lower electrode material is deposited over a semiconductor substrate including a lower electrode contact plug so as to form a sacrificial insulation film. After the sacrificial insulation film and a lower electrode material are etched using a dry etching process, additional lower electrode material is deposited and etched back so as to form a lower electrode. As a result, a margin or region between a lower electrode contact plug and the lower electrode can be guaranteed.

### CROSS-REFERENCE TO RELATED APPLICATION

The priority of Korean patent application No. 10-2010-0103519 filed on 22 Oct. 2010, the disclosure of which is hereby incorporated in its entirety by reference, is claimed.

### BACKGROUND OF THE INVENTION

Embodiments of the present invention relate to a method for manufacturing a semiconductor device.

In case of a semiconductor device such as a Dynamic Random Access Memory (DRAM), it is necessary to reduce the area occupied by the semiconductor device in proportion to the increasing degree of integration, and necessary electrostatic capacitance needs to be maintained or increased. Generally, there are a variety of methods to guarantee sufficient cell electrostatic capacitance within a limited area, for example, a method for using a high dielectric material as a dielectric film, a method for reducing thickness of the dielectric film, a method for increasing an effective region of a lower electrode, etc. Specifically, the method for using the high dielectric material requires time and material investment, for example, the introduction of new equipment or installations, the necessity of verifying the reliability and productivity of a dielectric film, low-temperature processing of a subsequent process, etc. Accordingly, the method for increasing the effective region has an advantage in that a conventional dielectric film can be continuously used and the implementation of a fabrication process becomes relatively easy, so that it has been widely used in the actual fabrication process due to the above-mentioned advantages.

There are a variety of methods to increase an effective region of the lower electrode, for example, a method for configuring a lower electrode in the form of a three-dimensional (3D) structure (such as a cylinder or a fin), a method for growing a Hemi Spherical Grain (HSG) on a lower electrode, a method for increasing the height of a lower electrode, etc. Specifically, the method for growing the HSG may cause unexpected problems in guaranteeing a Critical Dimension (CD) of at least a predetermined level between lower electrodes, and may cause a bridge between lower electrodes due to infrequent HSG desquamation, so that it is difficult for the aforementioned HSG growing method to be applied to a semiconductor device based on the design rule of 0.14 μm or less. Therefore, in general, in order to increase cell electrostatic capacitance, a variety of methods for configuring a lower electrode in the form of a 3D structure and increasing the height of the lower electrode have been widely used. A representative example of such methods is a method for forming a cylindrical lower electrode or a stack-shaped lower electrode.

Specifically, the conventional method for forming the cylindrical lower electrode necessarily includes removing a sacrificial insulation film from a peripheral part of the lower electrode, and depositing a dielectric film over the lower electrode. In this case, the dielectric material contained in the dielectric film is not deposited only over the lower electrode but is deposited between neighboring lower electrodes, such that all the cells can share a dielectric material and an upper electrode formed over the dielectric material. Provided that the cells share and use such a dielectric material, capacitance (storage capacitance) among all the lower electrodes may be interfered or distorted.

As described above, in order to maximize cell capacitance for improving refresh characteristics of the conventional cylindrical lower electrode, the height of each lower electrode becomes increased and the spacing between the lower electrode contact plugs becomes smaller. As a result, there arises a bridge between lower electrodes, and it is difficult to guarantee a contact region between the lower electrode contact plug and the lower electrode.

### BRIEF SUMMARY OF THE INVENTION

Various embodiments of the present invention are directed to providing a method for manufacturing a semiconductor device that substantially obviates one or more problems due to limitations and disadvantages of the related art.

An embodiment of the present invention relates to a method for manufacturing a semiconductor device in which a lower electrode material is deposited over a semiconductor substrate including a lower electrode contact plug so as to form a sacrificial insulation film. In addition, after the sacrificial insulation film and a lower electrode material are etched using a dry etching process, the lower electrode material is re-deposited and etched back so as to form a lower electrode, resulting in a guarantee of a margin or region between a lower electrode contact plug and the lower electrode.

In accordance with an aspect of the present invention, a method for manufacturing a semiconductor device includes forming a first conductive pattern coupled to a contact plug and an insulation film pattern over a semiconductor substrate including the contact plug; forming a second conductive layer over the insulation film pattern, the first conductive pattern and the semiconductor substrate; and forming a lower electrode by removing not only the second conductive layer that is formed over the insulation film pattern and the semiconductor substrate, but also the insulation film pattern.

The formation of the conductive pattern and the insulation film pattern may include: forming a first conductive layer and an insulation film; and etching the insulation film and the first conductive layer until the semiconductor substrate is exposed.

The first conductive layer may be configured in a form of a laminated structure of a titanium (Ti) film and a titanium nitride (TiN) film.

The titanium (Ti) film may be formed to have a thickness of 50 nm˜100 nm.

The titanium nitride (TiN) film may be formed to have a thickness of 200 nm˜300 nm.

The insulation film may include a Phosphorsilicate Glass (PSG) film.

The method may further include forming an etch stop layer between the semiconductor substrate and the first conductive layer.

The etch stop layer may include a nitride film.

The etching of the insulation film and the first conductive layer may use a dry etching process.

The insulation film may be etched using C₄H₈ gas of 36 sccm, C₃H₈ gas of 38 sccm, argon (Ar) gas of 400 sccm, O₂ gas of 38 sccm, CO gas of 100 sccm, and CH₂F₂ gas of 10 sccm.

The etching of the first conductive layer may be performed via an in-situ etching process.

The etching of the first conductive layer may be performed using argon (Ar) gas of 170 sccm and Cl₂ gas of 30 sccm.

The second conductive layer may use an etch-back process.

The removing of the insulation film pattern may be performed using a wet etching process.

The method may further include, after forming the lower electrode, forming a dielectric film and an upper electrode over the lower electrode.

In an embodiment, a method for manufacturing a semiconductor device includes forming first and second stack patterns over a substrate, wherein the first stack pattern includes a first conductive pattern and a first sacrificial pattern, and wherein the second stack pattern includes a second conductive pattern and a second sacrificial pattern; forming a third conductive pattern over sidewalls of the first stack and sidewalls of the second stack; and removing the first and the second sacrificial patterns, wherein the third conductive pattern formed over the sidewalls of the first stack pattern is coupled to the first conductive pattern to form a first lower storage electrode pattern, wherein the third conductive pattern formed over the sidewalls of the second stack pattern is coupled to the second conductive pattern to form a second lower storage electrode pattern, wherein the first and the second lower storage electrode patterns are electrically separately.

The method further includes forming first and second contact plugs coupling the first and the second conductive patterns to storage junction regions of the substrate, respectively.

The step of forming the third conductive pattern includes forming the third conductive pattern extending from over the first stack pattern to over the second stack pattern; and patterning away the third conductive pattern between the first stack pattern and the second stack pattern so as to be electrically separate.

The method further includes patterning away the third conductive pattern over an upper surface of the first stack pattern and an upper surface of the second stack pattern to expose the first and the second sacrificial patterns; and removing the first and the second sacrificial patterns.

The first and the second lower storage electrode patterns are U-shape patterns, wherein the bottom of the U-shape patterns are formed of the first and the second conductive patterns, respectively, and wherein the sidewalls of the U-shape patterns are formed of the third conductive patterns, respectively.

### BRIEF DESCRIPTION OF THE DRAWINGS

FIGS. 1A to 1D are cross-sectional views illustrating a method for manufacturing a semiconductor device according to embodiments of the present invention.

### DESCRIPTION OF EMBODIMENTS

Reference will now be made in detail to embodiments of the present invention, examples of which are illustrated in the accompanying drawings. Wherever possible, the same reference numbers will be used throughout the drawings to refer to the same or like parts. A method for forming a semiconductor device according to embodiments of the present invention will hereinafter be described with reference to the appended drawings.

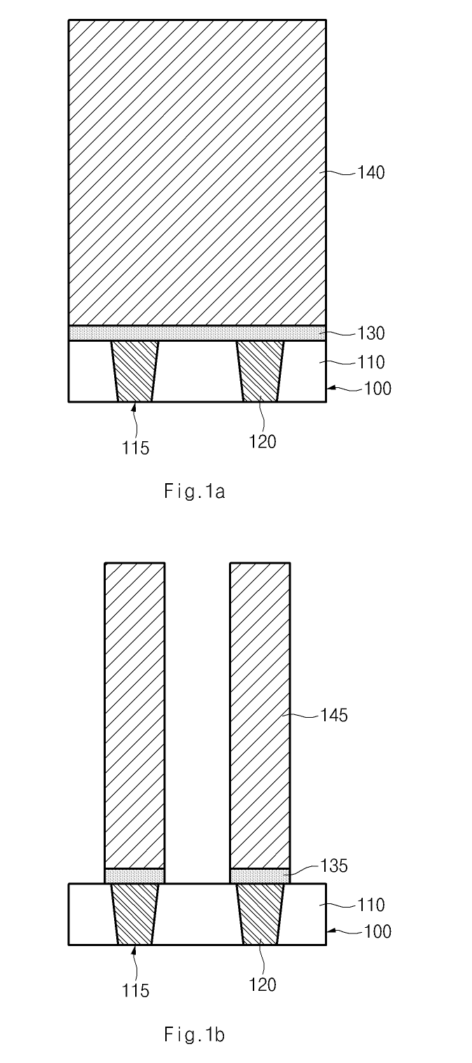

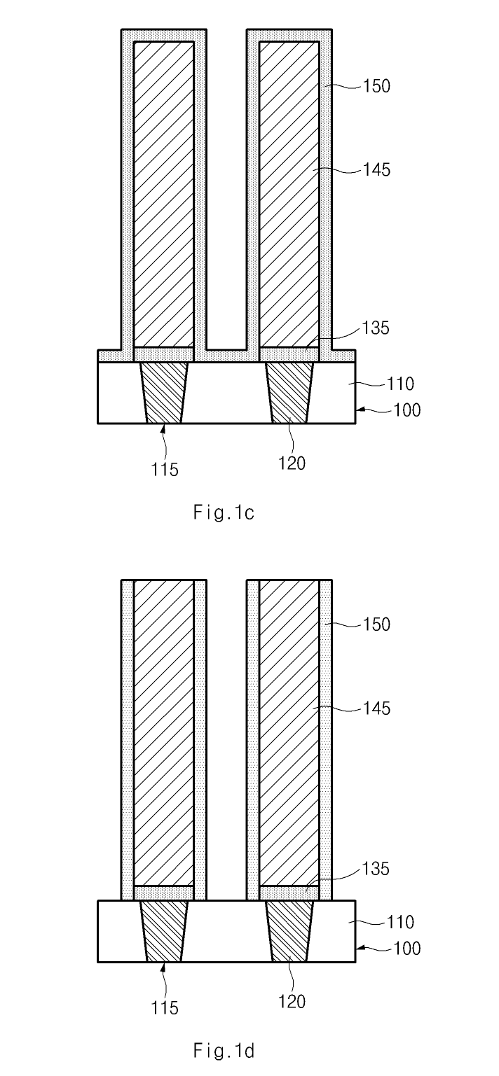

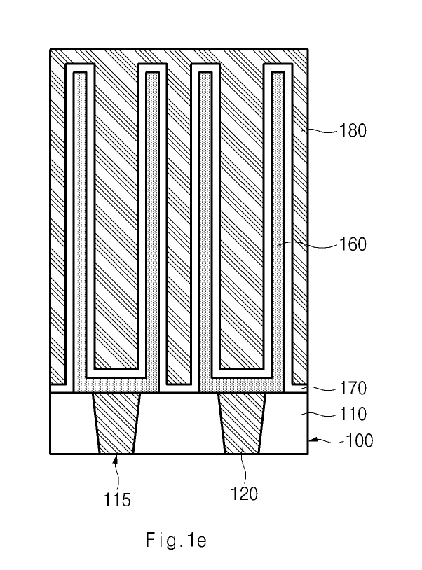

FIGS. 1A to 1E are cross-sectional views illustrating a method for manufacturing a semiconductor device according to embodiments of the present invention.

Referring to FIG. 1A, an interlayer insulation film 110 is formed over a semiconductor substrate 100. Preferably, the interlayer insulation film 110 may be formed of an oxide film.

After forming a photoresist film (not shown) over the interlayer insulation film 110, a photoresist pattern (not shown) is formed by an exposure and development process based on a mask for forming a lower electrode contact plug. The interlayer insulation film 110 is etched using the photoresist pattern as an etch mask, so that a lower electrode contact hole 115 is formed.

After depositing a conductive material over the entire surface including the lower electrode contact hole 115, a conductive material is planarized and etched using a Chemical Mechanical Polishing (CMP) process until the interlayer insulation film 110 is exposed, thereby forming a lower electrode contact plug 120. After forming a lower electrode contact plug 120, it is possible to form an etch stop layer between the semiconductor substrate 100 and the first conductive layer 130

Subsequently, a first conductive layer 130 is formed over the lower electrode contact plug 120 and the interlayer insulation film 110. In this case, it is preferable that the first conductive layer 130 be configured in the form of a laminated structure of a titanium (Ti) film and a titanium nitride (TiN) film. Preferably, the titanium (Ti) film may be formed to have a thickness of 50 nm˜100 nm, and the titanium nitride (TiN) film may be formed to have a thickness of 200 nm˜300 nm.

Next, an insulation film 140 is formed over the first conductive layer 130. In this case, the insulation film 140 may be formed of an oxide film and have a thickness of 1000 nm˜2000 nm. In more detail, it is preferable that the insulation film 140 be formed of a Phosphorsilicate Glass (PSG) film. Thereafter, the insulation film 140 is planarized and etched using a CMP process.

Referring to FIG. 1B, a hard mask layer (not shown), a reflection prevention film (not shown), and a photoresist film are sequentially formed over the insulation film 140, and the photoresist pattern (not shown) is formed by an exposure and development process using a mask for forming a lower electrode. The reflection prevention film and the hard mask layer are etched using the photoresist pattern as an etch mask until the insulation film 140 is exposed, so that a reflection prevention film pattern (not shown) and a hard mask pattern (not shown) are formed. After removing the reflection prevention film pattern, the insulation film 140 and the first conductive layer 130 are etched using the hard mask pattern as an etch mask until the interlayer insulation film 110 is exposed, thereby forming the insulation film pattern 145 and the first conductive pattern 135. Preferably, the reflection prevention film may be etched using CF₄ gas of 140 sccm, CHF₃ gas of 10 sccm, and O₂ gas of 10 sccm, and the hard mask layer may be etched using O₂ gas of 750 sccm. In this case, it is preferable that a dry etching method be used to etch the insulation film 140 and the first conductive layer 130. In more detail, the insulation film 140 may be etched using C₄H₈ gas of 36 sccm, C₃H₈ gas of 38 sccm, argon (Ar) gas of 400 sccm, O₂ gas of 38 sccm, CO gas of 100 sccm, and CH₂F₂ gas of 10 sccm. Preferably, the first conductive layer 130 may be formed by an in-situ etching method, and may be etched using argon (Ar) gas of 170 sccm and Cl₂ gas of 30 sccm.

Referring to FIG. 1C, a second conductive layer 150 is formed over an insulation film pattern 145, a first conductive pattern 135 and a first insulation film 110. In this case, it is preferable that the second conductive layer 150 may be configured in the form of a laminated structure of a titanium (Ti) film and a titanium nitride (TiN) film. Preferably, the titanium (Ti) film may have a thickness of 50 nm˜100 nm, and the titanium nitride (TiN) film may have a thickness of 200 nm˜300 nm.

Referring to FIG. 1D, a portion of the second conductive layer 150 formed over the insulation film pattern 145 and a portion of the second conductive layer 150 formed over the first insulation film 110 are removed using an etch-back process. A conductive path exists between remaining pillars of the second conductive layer 150 and the first conductive layer 135 so that after the etch-back process, remaining portions of the second conductive layer 150 and first conductive layer 135 become the lower electrode 160. By such an etch-back process, neighboring lower electrodes 160 are separated from each other. Preferably, during the etch-back process, the second conductive layer 150 may be partially removed using 170 sccm of argon (Ar) gas and 60 sccm of Cl₂ gas.

Referring to FIG. 1E, after etching, the insulation film pattern 145 is removed using a wet etching process. Preferably, during the wet etching process, the insulation film pattern 145 may be removed using a Buffered Oxide Etchant (BOE) solution.

Finally, a dielectric film 170 and an upper electrode 180 are sequentially formed over the lower electrode 160 and the first insulation film 110, resulting in the embodiment shown in FIG. 1D. In this case, the dielectric film 170 may include ZrO₂ or Al₂O₃.

As is apparent from the above description, in accordance with the aforementioned method for manufacturing the semiconductor device, a lower electrode material is deposited over a semiconductor substrate including a lower electrode contact plug so as to form a sacrificial insulation film, for example, the insulation film 140. After the sacrificial insulation film and the lower electrode material are etched using a dry etching process, additional lower electrode material, for example, the second conductive layer 150, is deposited and etched back so as to form a lower electrode. As a result, tolerance in forming the lower electrode can be increased.

The above embodiments of the present invention are illustrative and not limiting. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device comprising:
forming a first conductive pattern coupled to a contact plug and an insulation film pattern over a semiconductor substrate including the contact plug;
forming a second conductive layer over the insulation film pattern, the first conductive pattern and the semiconductor substrate; and
forming a lower electrode by removing a portion of the second conductive layer that is formed over the insulation film pattern, removing a portion of the second conductive layer that is formed over the semiconductor substrate, and removing the insulation film pattern.

2. The method according to claim 1, wherein the formation of the first conductive pattern and the insulation film pattern includes:
forming a first conductive layer and an insulation film over the semiconductor substrate; and
etching the insulation film and the first conductive layer until the semiconductor substrate is exposed.

3. The method according to claim 2, wherein the first conductive layer is a laminated structure comprising a titanium (Ti) film and a titanium nitride (TiN) film.

4. The method according to claim 3, wherein the titanium (Ti) film is formed to have a thickness of 50 nm˜100 nm.

5. The method according to claim 3, wherein the titanium nitride (TiN) film is formed to have a thickness of 200 nm˜300 nm.

6. The method according to claim 2, wherein the insulation film includes a Phosphorsilicate Glass (PSG) film.

7. The method according to claim 2, further comprising:
forming an etch stop layer between the semiconductor substrate and the first conductive layer.

8. The method according to claim 7, wherein the etch stop layer includes a nitride film.

9. The method according to claim 2, wherein the etching of the insulation film and the first conductive layer uses a dry etching process.

10. The method according to claim 9, wherein the insulation film is etched using 36 sccm of C₄H₈ gas, 38 sccm of C₃H₈ gas, 400 sccm of argon (Ar) gas, 38 sccm of O₂ gas of, 100 sccm of CO gas of, and 10 sccm of CH₂F₂ gas.

11. The method according to claim 9, wherein the etching of the first conductive layer is performed via an in-situ etching process.

12. The method according to claim 11, wherein the etching of the first conductive layer is performed using 170 sccm of argon (Ar) gas and 30 sccm of Cl₂ gas.

13. The method according to claim 1, wherein the second conductive layer uses an etch-back process.

14. The method according to claim 1, wherein the removing of the insulation film pattern is performed using a wet etching process.

15. The method according to claim 1, further comprising:
after forming the lower electrode,
forming a dielectric film and an upper electrode over the lower electrode.

16. A method for manufacturing a semiconductor device comprising:
forming an interlayer insulation film over a substrate;
forming a contact plug in the insulation film;
forming a first conductive layer and insulation film over the contact plug;
etching the first conductive layer and the insulation film to expose the interlayer insulation film;
forming a second conductive layer coupled to the first conductive layer over the contact plug; and
removing a portion of the second conductive layer over an upper surface of the insulation film and removing a portion of the second conductive layer over the interlayer insulation film so that the remaining portions of the first conductive layer and the second conductive layer form a lower electrode.

17. A method for manufacturing a semiconductor device comprising:
forming first and second stack patterns over a substrate, wherein the first stack pattern includes a first conductive pattern and a first sacrificial pattern, and wherein the second stack pattern includes a second conductive pattern and a second sacrificial pattern;
forming a third conductive pattern over sidewalls of the first stack and sidewalls of the second stack; and
removing the first and the second sacrificial patterns,
wherein the third conductive pattern formed over the sidewalls of the first stack pattern is coupled to the first conductive pattern to form a first lower storage electrode pattern,
wherein the third conductive pattern formed over the sidewalls of the second stack pattern is coupled to the second conductive pattern to form a second lower storage electrode pattern,
wherein the first and the second lower storage electrode patterns are electrically separately.

18. The method of claim 17, wherein the step of forming the third conductive pattern comprising:
forming the third conductive pattern extending from over the first stack pattern to over the second stack pattern; and
patterning away the third conductive pattern between the first stack pattern and the second stack pattern so as to be electrically separate.

19. The method of claim 18, the method further comprising:
patterning away the third conductive pattern over an upper surface of the first stack pattern and an upper surface of the second stack pattern to expose the first and the second sacrificial patterns; and
removing the first and the second sacrificial patterns.

20. The method of claim 17, wherein the first and the second lower storage electrode patterns are U-shape patterns,
wherein the bottom of the U-shape patterns are formed of the first and the second conductive patterns, respectively, and
wherein the sidewalls of the U-shape patterns are formed of the third conductive patterns, respectively.
